(19) United States
(12) Patent Application Publication
(10) Pub. No.: US 2025/0305183 A1
(43) Pub. Date: Oct. 2, 2025

(54) GROUP III ELEMENT NITRIDE SUBSTRATE AND PRODUCTION METHOD FOR GROUP III ELEMENT NITRIDE SUBSTRATE

(71) Applicant: NGK INSULATORS, LTD., Nagoya-shi (JP)

(72) Inventor: Shohei OUE, Nagoya-shi (JP)

(21) Appl. No.: 19/234,356

(22) Filed: Jun. 11, 2025

Related U.S. Application Data
(63) Continuation of application No. PCT/JP2022/045892, filed on Dec. 13, 2022.

(51) Int. Cl. C30B 29/40; C30B 25/20; C30B 29/60

(52) U.S. Cl. CPC C30B 29/406; C30B 25/20; C30B 29/60

(57) ABSTRACT

A Group-III element nitride substrate includes a first main surface and a second main surface facing each other, wherein a fluctuation width of a Young's modulus in a thickness direction of the Group-III element nitride substrate is 50% or less.

### CROSS-REFERENCE TO RELATED APPLICATIONS

This application is a continuation under 35 U.S.C. 120 of International Application PCT/JP2022/045892 having the International Filing Date of Dec. 13, 2022. The identified application is fully incorporated herein by reference.

### BACKGROUND OF THE INVENTION

### Technical Field

One or more embodiments of the present invention relates to a Group-III element nitride substrate and a method of producing a Group-III element nitride substrate.

### Background Art

Group-III element nitride substrates have been used as the substrates of various devices, such as a light-emitting diode, a semiconductor laser, and a power IC.

The Group-III element nitride substrate may be obtained by, for example, as described in Patent Literature 1, adopting, as a base substrate, a substrate including a material different in composition such as a sapphire substrate, and heteroepitaxially growing a Group-III element nitride crystal on the base substrate.

### CITATION LIST

### Patent Literature

[PTL 1] JP 2005-136167 A

### SUMMARY OF THE INVENTION

However, the Group-III element nitride substrate obtained by the heteroepitaxial growth has a problem in that warping is liable to occur.

In view of the foregoing, a primary object of the present invention is to provide a Group-III element nitride substrate in which the occurrence of warping is suppressed.

1. According to an embodiment of the present invention, there is provided a Group-III element nitride substrate, including a first main surface and a second main surface facing each other, wherein a fluctuation width of a Young's modulus in a thickness direction of the Group-III element nitride substrate is 50% or less.

2. The Group-III element nitride substrate according to the above-mentioned item 1 may be a freestanding substrate of a Group-III element nitride crystal.

3. The Group-III element nitride substrate according to the above-mentioned item 1 or 2 may have a thickness of 250 μm or more and 800 μm or less.

4. In the Group-III element nitride substrate according to any one of the above-mentioned items 1 to 3, the fluctuation width of the Young's modulus in the thickness direction may be 35% or less.

5. In the Group-III element nitride substrate according to any one of the above-mentioned items 1 to 4, the fluctuation width of the Young's modulus in the thickness direction may be 1% or more.

6. In the Group-III element nitride substrate according to any one of the above-mentioned items 1 to 5, the Young's modulus may increase from a second main surface side to a first main surface side.

7. In the Group-III element nitride substrate according to any one of the above-mentioned items 1 to 6, an absolute value of a difference between a Young's modulus in the first main surface and a Young's modulus in the second main surface may be 100 GPa or less.

8. In the Group-III element nitride substrate according to any one of the above-mentioned items 1 to 7, the thickness direction may be substantially a c-axis direction of a Group-III element nitride crystal.

9. In the Group-III element nitride substrate according to any one of the above-mentioned items 1 to 8, the Young's modulus may be measured by a nanoindentation method.

10. According to an embodiment of the present invention, there is provided a method of producing the Group-III element nitride substrate of any one of the above-mentioned items 1 to 9, the method including: preparing a seed crystal substrate including a base substrate including an upper surface and a lower surface facing each other, and a seed crystal film to be formed on the upper surface of the base substrate; growing a Group-III element nitride crystal on the seed crystal film of the seed crystal substrate; and removing the base substrate from the Group-III element nitride crystal, wherein the growing the Group-III element nitride crystal is performed by changing a growth speed of the Group-III element nitride crystal.

11. In the production method according to the above-mentioned item 10, the base substrate may contain a material different in composition from the Group-III element nitride crystal.

### Advantageous Effects of Invention

According to the embodiment of the present invention, the Group-III element nitride substrate in which the occurrence of warping is suppressed can be provided.

### BRIEF DESCRIPTION OF THE DRAWINGS

FIG. 1 is a schematic sectional view for illustrating the schematic configuration of a Group-III element nitride substrate according to one embodiment of the present invention.

FIG. 2 is a plan view of the Group-III element nitride substrate illustrated in FIG. 1.

FIG. 3A is a view for illustrating a production process for a Group-III element nitride substrate according to one embodiment.

FIG. 3B is a view subsequent to FIG. 3A.

FIG. 3C is a view subsequent to FIG. 3B.

FIG. 4A is a sectional view for illustrating an example of warping that may occur in a laminated substrate.

FIG. 4B is a sectional view for illustrating an example of warping that may occur in a freestanding substrate.

FIG. 5 is a schematic sectional view for illustrating the schematic configuration of a device substrate according to one embodiment of the present invention.

FIG. 6 is a sectional view for illustrating a measurement site for a Young's modulus.

### DESCRIPTION OF THE EMBODIMENTS

Embodiments of the present invention are described below with reference to the drawings, but the present invention is not limited to those embodiments. For clearer illustration, some widths, thicknesses, shapes, and the like of respective portions may be schematically illustrated in the drawings in comparison to the embodiments. However, the widths, the thicknesses, the shapes, and the like are each merely an example, and do not limit the understanding of the present invention. In addition, in the drawings, the same or similar elements are denoted by the same reference symbols, and repetitive description thereof may be omitted.

### A. Group-III Element Nitride Substrate

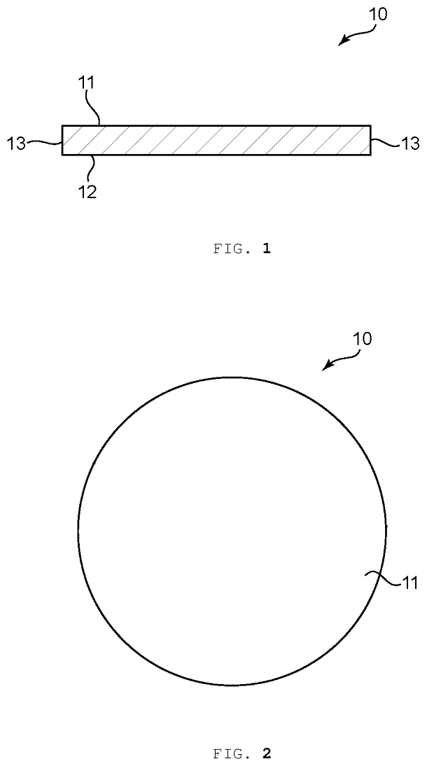

FIG. 1 is a schematic sectional view for illustrating the schematic configuration of a Group-III element nitride substrate according to one embodiment of the present invention. FIG. 2 is a plan view of the Group-III element nitride substrate illustrated in FIG. 1. A Group-III element nitride substrate 10 has a plate shape and includes a first main surface 11 and a second main surface 12 facing each other. The main surfaces are linked to each other via a side surface 13.

In the illustrated examples, the Group-III element nitride substrate has a disc shape (wafer), but the shape is not limited thereto and any appropriate shape may be adopted. The size of the Group-III element nitride substrate may be appropriately set in accordance with purposes. The diameter of the Group-III element nitride substrate having a disc shape is, for example, 50 mm or more and 300 mm or less, and may be 75 mm or more, or 100 mm or more. According to the Group-III element nitride substrate having a large size (e.g., having a diameter of 75 mm or more), for example, the productivity of a device having a large size can be improved.

The thickness of the Group-III element nitride substrate is, for example, 250 μm or more and 800 μm or less, preferably 300 μm or more and 750 μm or less, more preferably 350 μm or more and 725 μm or less.

The Group-III element nitride substrate includes a Group-III element nitride crystal. For example, aluminum (Al), gallium (Ga), or indium (In) is used as a Group-III element for forming a Group-III element nitride. Those elements may be used alone or in combination thereof. Specific examples of the Group-III element nitride include aluminum nitride (AlₓN), gallium nitride (Ga_{y}N), indium nitride (In_{z}N), aluminum gallium nitride (AlₓGa_{y}N), gallium indium nitride (Ga_{y}In_{z}N), aluminum indium nitride (AlₓIn_{z}N), and aluminum gallium indium nitride (AlₓGa_{y}In_{z}N). In each of the chemical formulae in parentheses, typically, x+y+z=1 is satisfied.

The Group-III element nitride may contain a dopant. Examples of the dopant include: p-type dopants, such as beryllium (Be), magnesium (Mg), strontium (Sr), cadmium (Cd), iron (Fe), manganese (Mn), and zinc (Zn); and n-type dopants, such as silicon (Si), germanium (Ge), tin (Sn), and oxygen (O). Those dopants may be used alone or in combination thereof.

In the Group-III element nitride crystal, typically, a <0001> direction is a c-axis direction, a <1-100> direction is an m-axis direction, and a <11-20> direction is an a-axis direction. In addition, a crystal plane perpendicular to the c-axis is a c-plane, a crystal plane perpendicular to the m-axis is an m-plane, and a crystal plane perpendicular to the a-axis is an a-plane. The relationship between a crystal axis of the Group-III element nitride crystal and a thickness direction of the Group-III element nitride substrate 10 is not particularly limited.

In one embodiment, the thickness direction of the Group-III element nitride substrate 10 is substantially the c-axis direction. Specifically, the thickness direction of the Group-III element nitride substrate 10 is parallel or approximately parallel to the c-axis. In addition, substantially, the first main surface 11 is a Group-III element polar surface on a (0001) plane side, and the second main surface 12 is a nitrogen polar surface on a (000-1) plane side. Specifically, the first main surface 11 may be parallel to a (0001) plane, or may be tilted with respect to the (0001) plane. The angle of the tilt of the first main surface 11 with respect to the (0001) plane is, for example, 10° or less, and may be 5° or less, 2° or less, or 1° or less. The second main surface 12 may be parallel to a (000-1) plane, or may be tilted with respect to the (000-1) plane. The angle of the tilt of the second main surface 12 with respect to the (000-1) plane is, for example, 10° or less, and may be 5° or less, 2° or less, or 1° or less. The first main surface 11 is not limited to the plane parallel to the (0001) plane or the plane tilted with respect to the (0001) plane, and substantially, may be parallel to a non-polar surface, such as an a-plane (11-20) or an m-plane (1-100), or may be parallel to a semipolar surface, such as a (11-22) plane or a (1-101) plane. The term “thickness direction” refers to a direction perpendicular to a main surface.

The Young's modulus of the Group-III element nitride substrate 10 may be typically from 100 GPa to 300 GPa.

In the Group-III element nitride substrate 10, the Young's modulus may fluctuate in the thickness direction. A fluctuation width of the Young's modulus in the thickness direction of the Group-III element nitride substrate 10 is, for example, 50% or less, preferably 35% or less, more preferably 25% or less, still more preferably 15% or less, and may be 5% or less. The fluctuation width of the Young's modulus in the thickness direction is, for example, 0% or more, preferably 1% or more. When such fluctuation width is satisfied, the occurrence of warping can be satisfactorily suppressed. The fluctuation width of the Young's modulus may be calculated from measured values obtained by measuring the Young's modulus, for example, every 5 μm to 400 μm in the thickness direction.

The way of fluctuation of the Young's modulus in the thickness direction is not particularly limited. In one embodiment, a Young's modulus in a first part positioned on a first main surface 11 side is higher than a Young's modulus in a second part positioned closer to a second main surface 12 side than the first part. For example, the Young's modulus may increase from the second main surface 12 side to the first main surface 11 side.

An absolute value of a difference between a Young's modulus in the first main surface 11 and a Young's modulus in the second main surface 12 is, for example, 100 GPa or less, preferably 80 GPa or less, more preferably 60 GPa or less, still more preferably 40 GPa or less, and may be 10 GPa or less. The absolute value of the difference between the Young's modulus in the first main surface 11 and the Young's modulus in the second main surface 12 is, for example, 0 GPa or more, preferably 3 GPa or more.

A value obtained by dividing the absolute value of the difference between the Young's modulus in the first main surface 11 and the Young's modulus in the second main surface 12 by a thickness of the Group-III element nitride substrate 10 is, for example, 0.20 GPa/μm or less, preferably 0.18 GPa/μm or less, more preferably 0.14 GPa/μm or less, still more preferably 0.10 GPa/μm or less, and may be 0.05 GPa/μm or less. The value obtained by dividing the absolute value of the difference between the Young's modulus in the first main surface 11 and the Young's modulus in the second main surface 12 by the thickness of the Group-III element nitride substrate 10 is, for example, 0 GPa/μm or more, preferably 0.02 GPa/μm or more.

The Young's modulus of the Group-III element nitride substrate 10 may be measured by any appropriate method. The Young's modulus may be measured by, for example, a nanoindentation method in conformity with ISO 14577. In the nanoindentation method, a measurement direction of the Young's modulus is typically the thickness direction of the Group-III element nitride substrate 10. In addition, for example, the Young's modulus may be measured by a tensile test. In addition, for example, the Young's modulus may be measured by a bending test. In each of the tensile test and the bending test, the measurement direction of the Young's modulus is typically a direction perpendicular to the thickness direction of the Group-III element nitride substrate 10.

The measurement of the Young's modulus may be performed by, for example, exposing a predetermined part of the Group-III element nitride substrate 10 through grinding, polishing, or the like. In addition, a measurement sample may be cut out from the predetermined part of the Group-III element nitride substrate 10, and the measurement sample having been cut out may be subjected to the measurement of the Young's modulus. The Young's modulus may be evaluated at any site in a plane of the Group-III element nitride substrate 10, but the fluctuation width of the Young's modulus in the thickness direction and the difference between Young's moduli are each preferably evaluated on substantially the same axis.

In the Group-III element nitride substrate according to the embodiment of the present invention, the occurrence of warping can be satisfactorily suppressed. Specifically, when the relationship in Young's modulus is satisfied in the Group-III element nitride substrate, the occurrence of warping can be satisfactorily suppressed. As a result of repeated trials and errors on the problem of warping, it has been found that, when a distribution of the Young's moduli in the thickness direction is controlled, warping can be alleviated. As the size (e.g., diameter) of the Group-III element nitride substrate becomes larger, the warping of the entirety of the substrate may become larger. When the warping of the entirety of the substrate becomes larger, for example, variations in characteristics of a functional layer, which is described later, to be formed on the substrate may become larger, and hence more strict control of warping is required. According to the embodiment of the present invention, even when the size of the Group-III element nitride substrate is large, the occurrence of warping can be satisfactorily suppressed.

The above-mentioned warping may be evaluated with a laser displacement sensor. As a measurement system of the laser displacement sensor, there are given, for example, a confocal system, a triangular ranging system, and an optical interference system, and the system may be appropriately selected in accordance with the surface roughness of a measurement target surface. The radius of curvature of the Group-III element nitride substrate calculated from the above-mentioned warping measured with the laser displacement sensor is preferably 15 m or more, more preferably 20 m or more, still more preferably 25 m or more, particularly preferably 30 m or more, most preferably 35 m or more.

### B. Production Method

A method of producing a Group-III element nitride substrate according to one embodiment of the present invention includes: preparing a seed crystal substrate including a base substrate and a seed crystal film; growing a Group-III element nitride crystal on the seed crystal film of the seed crystal substrate; and removing the base substrate from the Group-III element nitride crystal.

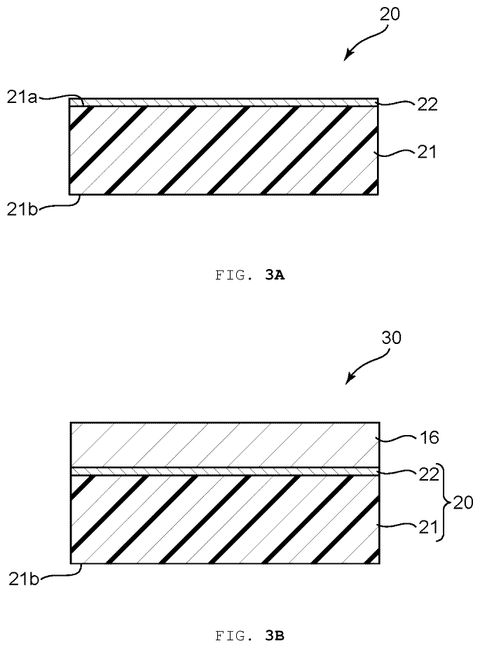

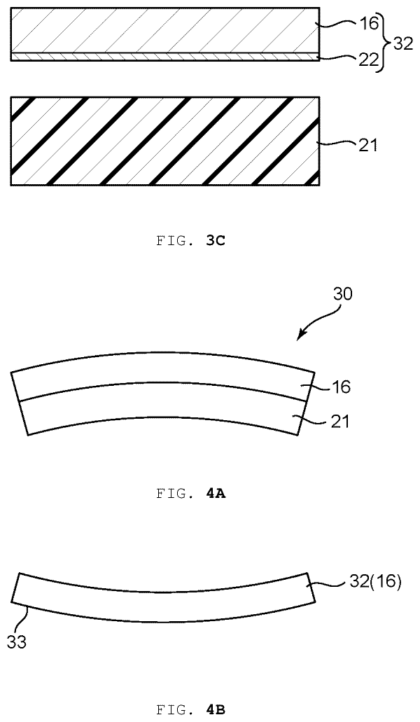

FIG. 3A to FIG. 3C are views for illustrating a production process for a Group-III element nitride substrate according to one embodiment. FIG. 3A is an illustration of a state in which a seed crystal film 22 has been formed on an upper surface 21a of a base substrate 21 including the upper surface 21a and a lower surface 21b facing each other to complete a seed crystal substrate 20.

For example, a substrate having such a shape and size that a Group-III element nitride substrate having a desired shape and size can be produced is used as the above-mentioned base substrate. Typically, the base substrate has a disc shape having a diameter of from 50 mm to 350 mm. The thickness of the base substrate is, for example, from 300 μm to 2,000 μm.

Any appropriate substrate may be used as the base substrate. The base substrate typically includes a monocrystalline body. Examples of a material for forming the base substrate include sapphire, crystal-oriented alumina, silicon, gallium oxide, aluminum gallium nitride, gallium arsenide, and silicon carbide (Sic).

The thickness of the above-mentioned seed crystal film is, for example, from 0.2 μm to 5 μm, preferably from 1 μm to 4 μm. Any appropriate material may be adopted as a material for forming the seed crystal film. A Group-III element nitride is typically used as the material for forming the seed crystal film. In one embodiment, gallium nitride is used.

The seed crystal film may be formed by any appropriate method. A vapor growth method is typically used as a method of forming the seed crystal film. Specific examples of the vapor growth method include a metal-organic chemical vapor deposition (MOCVD) method, a hydride vapor phase epitaxy (HVPE) method, a pulsed excitation deposition (PXD) method, a molecular-beam epitaxy (MBE) method, and a sublimation method. Of those, a MOCVD method is preferably used.

For example, the formation of the seed crystal film by the above-mentioned MOCVD method includes a first formation step and a second formation step in the stated order. Specifically, the first formation step includes forming a first layer (low-temperature grown buffer layer) (not shown) on the base substrate at a temperature T1 (e.g., from 450° C. to 550° C.), and the second formation step includes forming a second layer (not shown) at a temperature T2 (e.g., from 1,000° C. to 1,200° C.) higher than the temperature T1. The thickness of the first layer is, for example, from 20 nm to 50 nm. The thickness of the second layer is, for example, from 1 μm to 4 μm.

Next, the Group-III element nitride crystal is grown on the seed crystal film 22 of the seed crystal substrate 20 to form a Group-III element nitride crystal layer 16. Thus, a laminated substrate 30 is obtained as illustrated in FIG. 3B. The degree of growth of the Group-III element nitride crystal (thickness of the Group-III element nitride crystal layer 16) may be adjusted in accordance with a desired thickness of the Group-III element nitride substrate. Any appropriate direction may be selected as the growth direction of the Group-III element nitride crystal in accordance with, for example, applications or purposes. Specific examples thereof include: the normal direction of each of the above-mentioned c-plane, a-plane, and m-plane; and the normal direction of a plane tilted with respect to each of the above-mentioned c-plane, a-plane, and m-plane.

The Group-III element nitride crystal may be grown by any appropriate method. The method of growing the Group-III element nitride crystal is not particularly limited as long as a crystal direction substantially following the crystal direction of the above-mentioned seed crystal film can be achieved by the method. Specific examples of the method of growing the Group-III element nitride crystal include: vapor growth methods, such as a metal-organic chemical vapor deposition (MOCVD) method, a hydride vapor phase epitaxy (HVPE) method, a pulsed excitation deposition (PXD) method, a molecular-beam epitaxy (MBE) method, and a sublimation method; liquid phase growth methods, such as a flux method, an ammonothermal method, a hydrothermal method, and a sol-gel method; and a solid phase growth method utilizing grain growth of powder. Those methods may be used alone or in combination thereof.

The flux method (e.g., Na flux method) is preferably adopted as the method of growing the Group-III element nitride crystal. Details of such growth method are described in, for example, JP 5244628 B2, and the growth may be performed by appropriately adjusting various conditions of the described growth method.

For example, when the growth speed of the Group-III element nitride crystal is changed, the distribution of the Young's moduli in the Group-III element nitride substrate to be obtained can be achieved. Specifically, when the growth speed of the Group-III element nitride crystal is reduced in an initial stage of the growth as compared to a later stage of the growth, the distribution of the Young's moduli in the Group-III element nitride substrate to be obtained can be achieved. In the initial stage of the growth, as compared to the later stage of the growth, a defect such as dislocation tends to easily occur owing to a mismatch in a lattice constant between the base substrate 21 and the Group-III element nitride crystal to be grown. It is conceived that, when a large number of such defects are present, the Young's modulus is reduced. It has been found that, when the growth speed of the Group-III element nitride crystal is reduced in the initial stage of the growth as compared to the later stage of the growth, a reduction in Young's modulus in the initial stage of the growth can be suppressed. It is conceived that the suppression of the reduction in Young's modulus is based on, for example, a change in pore density or impurity concentration.

The change in growth speed may be achieved by, for example, adjusting a pressure. In one embodiment, when the Group-III element nitride crystal is grown on the seed crystal substrate 20, the growth speed is reduced by reducing the pressure in the initial stage of the growth as compared to the later stage of the growth. Thus, the distribution of the Young's moduli can be achieved. As the growth advances, the pressure may be continuously increased, or may be increased stepwise.

The change in growth speed may also be achieved by, for example, adjusting a temperature. In addition, for example, the change in growth speed of the Group-III element nitride crystal may be achieved by, for example, in the vapor growth method, adjusting the way of supplying (flow rate or flow velocity) of a raw material gas or adjusting the flow rate ratio of the raw material gas.

After the growth of the Group-III element nitride crystal, a freestanding substrate 32 is obtained by removing the base substrate 21 from the Group-III element nitride crystal (Group-III element nitride crystal layer 16) as illustrated in FIG. 3C. Typically, as illustrated in FIG. 3C, the freestanding substrate 32 may include the Group-III element nitride crystal layer 16 and the seed crystal film 22. For example, the freestanding substrate 32 is obtained by separating the Group-III element nitride crystal layer 16 from the base substrate 21. The Group-III element nitride crystal may be separated from the base substrate by any appropriate method. As a method of separating the Group-III element nitride crystal, there are given, for example, a method of causing spontaneous separation from the base substrate by utilizing a thermal shrinkage difference between the Group-III element nitride crystal and the base substrate in a temperature decrease step after the growth of the Group-III element nitride crystal, a separation method including chemical etching, and a laser liftoff method including laser light irradiation. When the Group-III element nitride crystal is separated by the laser liftoff method, typically, laser light is applied from a lower surface 21b side of the base substrate 21 of the laminated substrate 30. In addition, for example, the freestanding substrate may be obtained by grinding, or by cutting with a cutter such as a wire saw.

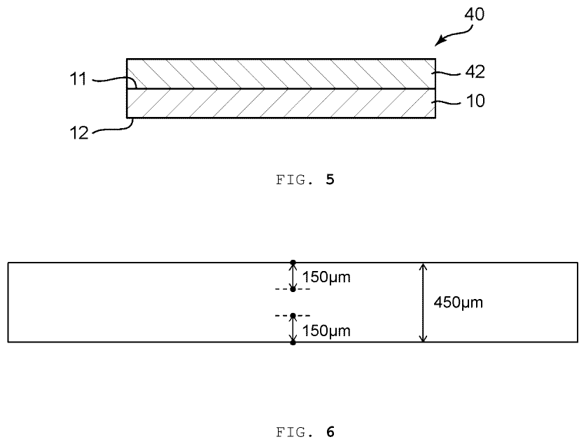

Warping may occur in the laminated substrate. FIG. 4A is a sectional view for illustrating an example of warping that may occur in a laminated substrate. FIG. 4B is a sectional view for illustrating an example of warping that may occur in a freestanding substrate. In FIGS. 4, hatching is omitted in a cross-section of each of the laminated substrate and the freestanding substrate for ease of viewing of the drawing. In addition, the illustration of the seed crystal film is omitted for convenience.

In the example illustrated in FIG. 4A, convex warping occurs on the Group-III element nitride crystal layer 16 side in the laminated substrate 30. The base substrate 21 may include a material different in composition (chemical composition) from the Group-III element nitride crystal layer 16. When the Group-III element nitride crystal is heteroepitaxially grown on such base substrate 21, warping tends to easily occur on the laminated substrate 30 to be obtained. A cause of the warping is conceived to be, for example, a stress that may occur owing to a mismatch in a lattice constant or a difference in coefficient of thermal expansion between the base substrate 21 and the Group-III element nitride crystal to be grown. The warping may occur when, for example, the temperature of the laminated substrate 30 is decreased after the Group-III element nitride crystal is grown at a high temperature (e.g., from 800° C. to 1,100° C.). When the coefficient of thermal expansion of the base substrate 21 is larger than the coefficient of thermal expansion of the Group-III element nitride crystal to be grown (e.g., when a sapphire substrate is used as the base substrate), as illustrated in FIG. 4A, convex warping may occur on the Group-III element nitride crystal layer 16 side. Meanwhile, when the coefficient of thermal expansion of the base substrate 21 is smaller than the coefficient of thermal expansion of the Group-III element nitride crystal to be grown (e.g., when a silicon substrate or a SiC substrate is used as the base substrate), convex warping may occur on the base substrate 21 side in contrast to the illustrated example.

In the freestanding substrate 32 obtained by removing the base substrate 21 from the laminated substrate 30 illustrated in FIG. 4A, for example, as illustrated in FIG. 4B, the direction of the warping is reversed, and convex warping may occur on a lower surface 33 side on which the base substrate 21 has been arranged.

As described above, in the freestanding substrate according to the embodiment of the present invention, the reduction in Young's modulus is suppressed in the initial stage of the growth thereof, and hence the occurrence of the warping as described above can be satisfactorily suppressed.

The freestanding substrate 32 may be used as it is for the above-mentioned Group-III element nitride substrate, or the freestanding substrate 32 may be subjected to any appropriate processing to provide the above-mentioned Group-III element nitride substrate.

An example of the processing to which the above-mentioned freestanding substrate is subjected is grinding (e.g., grinding with diamond abrasive grains) of its peripheral edge portion. Typically, the freestanding substrate is processed into the above-mentioned desired shape and size (e.g., a disc shape having a desired diameter) by grinding.

Another example of the processing to which the above-mentioned freestanding substrate is subjected is processing, such as grinding or polishing (e.g., lap polishing or chemical-mechanical polishing (CMP)), of its main surface (upper surface or lower surface). Typically, the freestanding substrate is thinned and flattened by the grinding and the polishing so as to have a desired thickness. In one embodiment, the freestanding substrate may be brought into a state of the Group-III element nitride crystal layer 16 alone (a single crystal growth layer alone) by removing the seed crystal film 22 through the processing of the main surface.

In addition, examples of the processing to which the above-mentioned freestanding substrate is subjected include chamfering of its outer peripheral edge, removal of an affected layer, and removal of a residual stress that may result from the affected layer.

### C. Application

A functional layer may be formed on the above-mentioned Group-III element nitride substrate. FIG. 5 is a schematic sectional view for illustrating the schematic configuration of a device substrate according to one embodiment of the present invention. A device substrate 40 includes the Group-III element nitride substrate 10 and a functional layer 42 formed on the first main surface (e.g., Group-III element polar surface) 11 of the Group-III element nitride substrate 10. The functional layer 42 is typically formed by epitaxially growing a crystal. As described above, the occurrence of warping can be satisfactorily suppressed in the Group-III element nitride substrate 10, and hence the functional layer 42 can be extremely satisfactorily formed. Specifically, in the formation of the functional layer 42, for example, heating unevenness at the time of heating from the Group-III element nitride substrate 10 side is prevented, and hence the functional layer 42 to be obtained can be excellent in uniformity of characteristics in its surface. In addition, when the Group-III element nitride substrate 10 in which the occurrence of warping is suppressed is used, workability in the production of the device substrate 40 can be excellent.

The above-mentioned functional layer may function as, for example, a light-emitting layer, a rectifying device layer, a switching device layer, and a power semiconductor layer. In one embodiment, the Group-III element nitride crystal is adopted as a material for forming the above-mentioned functional layer. For example, gallium (Ga), aluminum (Al), or indium (In) is used as a Group-III element for forming a Group-III element nitride. Those elements may be used alone or in combination thereof.

The second main surface (e.g., nitrogen polar surface) 12 of the Group-III element nitride substrate 10 may be subjected to processing, such as grinding or polishing, under a state in which the functional layer 42 has been formed on the Group-III element nitride substrate 10 (under a state in which the device substrate 40 has been formed).

EXAMPLES

The present invention is specifically described below by way of Examples, but the present invention is not limited to these Examples.

### Comparative Example 1

### Production of Seed Crystal Substrate

A gallium nitride film having a thickness of 2 μm was formed on a c-plane sapphire substrate having a diameter of 2 inches by a MOCVD method to produce a seed crystal substrate.

### Growth of Gallium Nitride Crystal

The growth of a gallium nitride crystal was performed with a crystal-producing apparatus including a pressure-resistant vessel capable of supplying a pressurized nitrogen gas, a rotary table rotatable in the pressure-resistant vessel, and an outer vessel to be mounted on the rotary table.

The obtained seed crystal substrate was arranged in an alumina crucible having a diameter of 200 mm in a glove box under a nitrogen atmosphere. Next, metal gallium and metal sodium were loaded into the crucible so that the atomic ratio Ga/(Ga+Na) (mol %) became 15 mol %, followed by the lidding of the crucible with an alumina plate. The crucible was loaded into a stainless steel-made inner vessel under the state, and the vessel was further loaded into a stainless steel-made outer vessel capable of storing the inner vessel, followed by the closing of the outer vessel with a lid mounted with a nitrogen-introducing pipe. The outer vessel was mounted on the rotary table placed in a heating portion in the crystal-producing apparatus under the state, and the pressure-resistant vessel of the crystal-producing apparatus was lidded and hermetically sealed.

Next, the inside of the pressure-resistant vessel was evacuated with a vacuum pump. Subsequently, while the heating portion was operated to heat a heating space so that its temperature became 870° C., a nitrogen gas was introduced into the pressure-resistant vessel until a pressure therein became 4.3 MPa, and the outer vessel was rotated about its central axis at a speed of 20 rpm clockwise and counterclockwise at a certain period. The outer vessel was held under the state for 100 hours. Thus, a gallium nitride crystal having a thickness of 700 μm was grown.

After that, the temperature was naturally cooled to room temperature, and the pressure was reduced to atmospheric pressure. After that, the lid of the pressure-resistant vessel was opened, and the crucible was removed from its inside. Solidified metal sodium in the crucible was removed, and a seed crystal substrate in which a gallium nitride crystal had been grown was recovered.

After that, at room temperature, UV laser light was applied from the sapphire substrate side of the seed crystal substrate in which the gallium nitride crystal had been grown to decompose the gallium nitride film of the seed crystal substrate. Thus, the grown gallium nitride crystal was separated from the sapphire substrate.

The peripheral edge portion of the separated gallium nitride crystal was ground with diamond abrasive grains so that the diameter thereof was adjusted to 50 mm. Next, the gallium nitride crystal was fixed to a ceramic-made surface plate for processing, and the gallium polar surface of the gallium nitride crystal was ground and polished with a grinder and a lapping apparatus. After that, the resultant surface was subjected to mirror finish with diamond abrasive grains each having a grain diameter of 0.1 μm. Next, the gallium nitride crystal was reversed and fixed to the ceramic-made surface plate for processing, and the nitrogen polar surface thereof was ground and polished in the same manner as in the gallium polar surface. After that, the resultant surface was subjected to mirror finish with diamond abrasive grains each having a grain diameter of 0.1 μm.

Thus, a gallium nitride substrate (wafer) having a thickness direction corresponding to a c-axis direction and having a thickness of 450 μm was produced.

### Example 1

A gallium nitride substrate was produced in the same manner as in Comparative Example 1 except that a gallium nitride crystal was grown by linearly changing a pressure (ambient pressure) in a heat-resistant vessel from 4.1 MPa to 4.3 MPa over 105 hours.

### Example 2

A gallium nitride substrate was produced in the same manner as in Comparative Example 1 except that a gallium nitride crystal was grown by linearly changing a pressure (ambient pressure) in a heat-resistant vessel from 3.9 MPa to 4.3 MPa over 110 hours.

### Example 3

A gallium nitride substrate was produced in the same manner as in Comparative Example 1 except that a gallium nitride crystal was grown by linearly changing a pressure (ambient pressure) in a heat-resistant vessel from 3.7 MPa to 4.3 MPa over 115 hours.

### Evaluation

The gallium nitride substrate (wafer) obtained in each of Examples and Comparative Example was subjected to the following evaluations. The evaluation results are summarized in Table 1.

### 1. Young's Modulus

As indicated by black circles in FIG. 6, the Young's modulus of each of four points at the center in the surface of the resultant gallium nitride substrate (wafer, thickness: 450 μm) in the thickness direction was measured. Specifically, the Young's modulus at each of the center of the upper surface and the center of the lower surface of the resultant gallium nitride substrate was measured, and then each of the upper surface and the lower surface was ground and polished to a thickness of 150 μm. Then, the Young's modulus at each of the center of the upper surface and the center of the lower surface after the grinding and polishing was measured.

A nanoindentation method was used for the measurement of the Young's modulus. Specifically, an ultra-fine indentation hardness tester (“ENT-NEXUS” manufactured by Elionix Inc.) was used as a measurement apparatus, a Berkovich-type diamond indenter was used as an indenter, and indentation was performed in the thickness direction under the conditions of a maximum load of 10 mN and a loading speed of 1 mN/sec, the resultant was kept for 5 seconds, and then unloading was performed at an unloading speed of 1 mN/sec. A curve of an indentation depth and the load was measured to calculate the Young's modulus.

The minimum value and maximum value of the measured values are shown in Table 1, and a fluctuation width (%) is calculated from the following equation (I).

$$Fluctuation width = ( maximum value - minimum value ) / average \times 100 \qquad ( I )$$

### 2. Radius of Curvature

The warping of a gallium nitride substrate (wafer, thickness: 450 μm) was measured with a laser displacement sensor (manufactured by Keyence Corporation, “CL-P015”), and the radius of curvature thereof was calculated from the warping. Specifically, the displacement of a main surface was measured with a confocal system by irradiating the main surface on a side opposite to a side on which the sapphire substrate had been arranged with laser light having a wavelength of 655 nm to provide a waveform for a region except for a region of 3 mm from an end of the gallium nitride substrate. An approximate curve was calculated from the obtained waveform by a least-squares method using a quadratic function. A difference between the maximum value and minimum value of the approximate curve was measured on each of two axes perpendicular to each other on the surface of the substrate, and the average of those values was defined as a warping S. In addition, a radius of curvature R was calculated from the obtained warping S with the following equation (II):

$$R = {D}^{2} / ( 8 \times S ) \qquad ( II )$$

where R represents the radius of curvature, D represents the diameter of the substrate, and S represents the warping, each of which is represented in the unit of [m].

TABLE 1

| | Young's modulus | | Radius of |
|---|---|---|---|
| | Measured value | Fluctuation width | curvature |
| | (GPa) | (%) | (m) |
| Example 1 | 174-246 | 34 | 26 |
| Example 2 | 215-246 | 13 | 40 |
| Example 3 | 244-246 | 0.8 | 34 |
| Comparative Example 1 | 143-246 | 53 | 11 |

In each of Examples and Comparative Example, convex warping was observed on the side on which the sapphire substrate had been arranged, but the degree thereof was much smaller in each of Examples.

### INDUSTRIAL APPLICABILITY

The Group-III element nitride substrate according to the embodiment of the present invention may be utilized as, for example, each of the substrates of various semiconductor devices.

What is claimed is:

1. A Group-III element nitride substrate, comprising a first main surface and a second main surface facing each other,
wherein a fluctuation width of a Young's modulus in a thickness direction of the Group-III element nitride substrate is 50% or less.

2. The Group-III element nitride substrate according to claim 1, wherein the Group-III element nitride substrate is a freestanding substrate of a Group-III element nitride crystal.

3. The Group-III element nitride substrate according to claim 1, wherein the Group-III element nitride substrate has a thickness of 250 μm or more and 800 μm or less.

4. The Group-III element nitride substrate according to claim 1, wherein the fluctuation width of the Young's modulus in the thickness direction is 35% or less.

5. The Group-III element nitride substrate according to claim 1, wherein the fluctuation width of the Young's modulus in the thickness direction is 1% or more.

6. The Group-III element nitride substrate according to claim 1, wherein the Young's modulus increases from a second main surface side to a first main surface side.

7. The Group-III element nitride substrate according to claim 1, wherein an absolute value of a difference between a Young's modulus in the first main surface and a Young's modulus in the second main surface is 100 GPa or less.

8. The Group-III element nitride substrate according to claim 1, wherein the thickness direction is substantially a c-axis direction of a Group-III element nitride crystal.

9. The Group-III element nitride substrate according to claim 1, wherein the Young's modulus is measured by a nanoindentation method.

10. A method of producing the Group-III element nitride substrate of claim 1, the method comprising:
preparing a seed crystal substrate including a base substrate including an upper surface and a lower surface facing each other, and a seed crystal film to be formed on the upper surface of the base substrate;
growing a Group-III element nitride crystal on the seed crystal film of the seed crystal substrate; and
removing the base substrate from the Group-III element nitride crystal,
wherein the growing the Group-III element nitride crystal is performed by changing a growth speed of the Group-III element nitride crystal.

11. The production method according to claim 10, wherein the base substrate contains a material different in composition from the Group-III element nitride crystal.
